(19) United States
(12) Patent Application Publication
(10) Pub. No.: US 2021/0023979 A1
(43) Pub. Date: Jan. 28, 2021

(54) ILLUMINATABLE VEHICLE ASSEMBLY AND VEHICLE ASSEMBLY ILLUMINATION METHOD

(71) Applicant: Ford Global Technologies, LLC, Dearborn, MI (US)

(72) Inventors: Paul Kenneth Dellock, Northville, MI (US); Stuart C. Salter, White Lake, MI (US); David Brian Glickman, Southfield, MI (US); Harry Lobo, Canton, MI (US); Cornel Lewis Gardner, Romulus, MI (US)

(21) Appl. No.: 16/519,126

(22) Filed: Jul. 23, 2019

(51) Int. Cl. B60Q 1/00; F21V 9/30; H05B 33/14; H05B 33/26; B60R 13/00; B60Q 1/50

(52) U.S. Cl. CPC B60Q 1/0023; F21V 9/30; H05B 33/145; F21Y 2115/20; B60R 13/005; B60Q 1/50; H05B 33/26

(57) ABSTRACT

An illuminatable vehicle assembly according to an exemplary aspect of the present disclosure includes, among other things, a dielectric layer that emits light. The dielectric layer is disposed between an anode layer and a cathode layer. The assembly further includes a color conversion layer that converts light emitted from the dielectric layer.

### TECHNICAL FIELD

This disclosure relates generally to a decorative assembly for a vehicle. In particular, the disclosure relates to a decorative assembly that can be selectively illuminated.

### BACKGROUND

Vehicles can include many decorative assemblies. Some decorative assemblies, such as badges, help to identify a model of the vehicle.

### SUMMARY

An illuminatable vehicle assembly according to an exemplary aspect of the present disclosure includes, among other things, a dielectric layer that emits light. The dielectric layer is disposed between an anode layer and a cathode layer. The assembly further includes a color conversion layer that converts light emitted from the dielectric layer.

In a further embodiment of the foregoing assembly, the anode layer is an indium anode layer and the cathode layer is an indium cathode layer.

In a further embodiment of any of the foregoing assemblies, the dielectric layer comprises quantum dots suspended in a dielectric material.

In a further embodiment of any of the foregoing assemblies, the dielectric layer comprises a perovskite material suspended in a dielectric material.

A further embodiment of any of the foregoing assemblies includes a substrate. The anode layer or the cathode layer is adhered to the substrate.

A further embodiment of any of the foregoing assemblies includes a radar sensor adjacent the substrate.

A further embodiment of any of the foregoing assemblies includes an outer layer atop the anode layer or the cathode layer. The outer layer including indium secured to a polymer or polymer based film.

In a further embodiment of any of the foregoing assemblies, the dielectric layer is configured to emit green light, and the color conversion layer is configured to convert the green light such to white light.

In a further embodiment of any of the foregoing assemblies, the color conversion layer includes a rylene dye.

In a further embodiment of any of the foregoing assemblies, the color conversion layer includes a phosphor.

A vehicle badge assembly according to another exemplary aspect of the present disclosure includes, among other things, a radar sensor, a substrate adjacent the radar sensor, a first indium layer atop the substrate, and a dielectric layer atop the first indium layer. The dielectric layer including a plurality of perovskite quantum dots that illuminate when charged. The assembly further includes a second indium layer atop the dielectric layer. The first and second indium layers are configured to place a charge across the dielectric layer to illuminate the plurality of perovskite quantum dots. The assembly further includes a color conversion layer atop the second indium layer. The color conversion layer includes a rylene dye. The color conversion layer converts a color of light emitted from the plurality of perovskite quantum dots. The assembly further includes an appearance layer atop the color conversion layer. The appearance layer includes indium and a polymer-based film.

In a further embodiment of the foregoing assembly, the color conversion layer converts green light emitted from the plurality of perovskite quantum dots into white light that is emitted through the appearance layer.

An illumination method according to yet another exemplary aspect of the present disclosure includes electrically charging a dielectric layer of a badge to cause the dielectric layer of the badge to emit light having a first color, and passing the light emitted from the dielectric layer through a color conversion layer that converts the light to a second color different than the first color.

A further embodiment of the foregoing method includes sandwiching the dielectric layer between an anode layer and a cathode layer.

In a further embodiment of any of the foregoing methods, the anode layer is an indium anode layer and the cathode layer is an indium cathode layer.

In a further embodiment of any of the foregoing methods, the first color is green and the second color is white.

A further embodiment of any of the foregoing methods includes placing a radar sensor behind the badge and communicating signals to and from the radar sensor. The signals passing through at least a portion of the badge.

In a further embodiment of any of the foregoing methods, the dielectric layer comprises a perovskite material suspended in a dielectric material.

In a further embodiment of any of the foregoing methods, the dielectric layer comprises quantum dots suspended in a dielectric material.

In a further embodiment of any of the foregoing methods, the color conversion layer includes a rylene dye.

The embodiments, examples and alternatives of the preceding paragraphs, the claims, or the following description and drawings, including any of their various aspects or respective individual features, may be taken independently or in any combination. Features described in connection with one embodiment are applicable to all embodiments, unless such features are incompatible.

### BRIEF DESCRIPTION OF THE FIGURES

The various features and advantages of the disclosed examples will become apparent to those skilled in the art from the detailed description. The figures that accompany the detailed description can be briefly described as follows:

FIG. 1 illustrates a vehicle incorporating an illuminatable assembly according to an exemplary embodiment of the present disclosure.

FIG. 2 shows a close-up front view of the illuminatable assembly of the vehicle of FIG. 1.

FIG. 3 illustrates a section view of the illuminatable assembly of FIG. 2.

FIG. 4 illustrates a schematic expanded view of layers of the assembly of FIGS. 2 and 3.

### DETAILED DESCRIPTION

Generally, this disclosure relates to an illuminatable vehicle assembly, which is a type of decorative assembly. A dielectric layer of the illuminatable assembly can be energized to cause the dielectric layer to emit light. A color conversion layer of the illuminatable assembly can then convert that light to a different color.

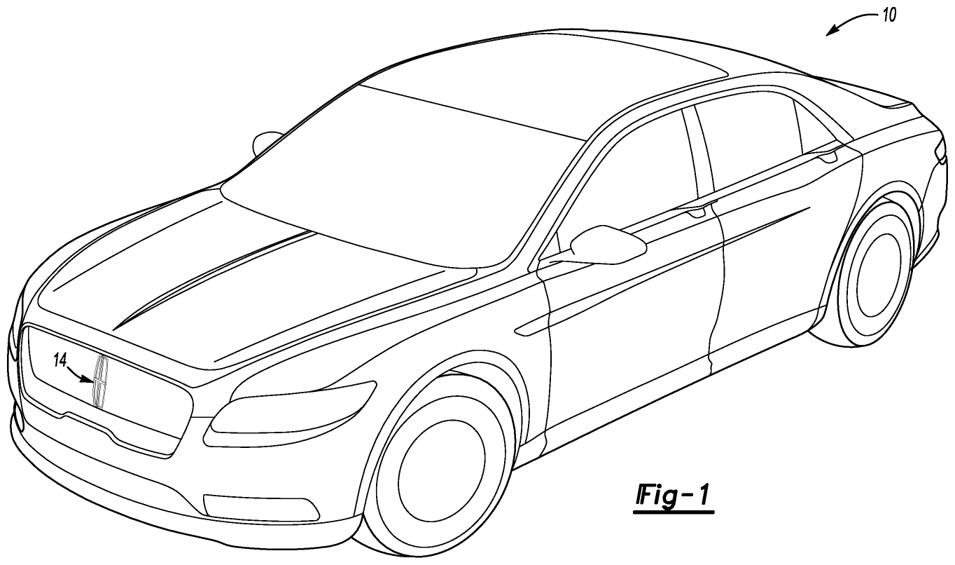

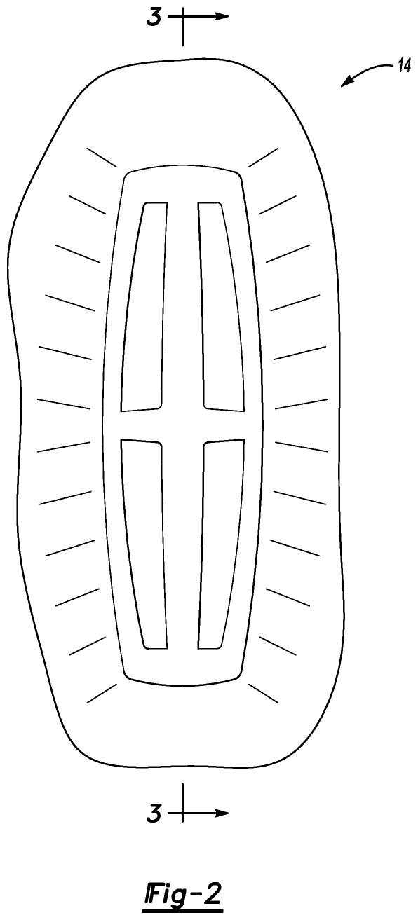

With reference to FIGS. 1 and 2, a vehicle 10 includes an illuminatable assembly 14. In this exemplary non-limiting embodiment, the illuminatable assembly 14 is a decorative badge that identifies the vehicle 10. Badges, in contrast to many trim components, can identify a brand of the vehicle 10. The badge can be a logo, a symbol, word, or some combination of these.

Although the exemplary illuminatable assembly 14 is a badge, the teachings of this disclosure can be applicable to illuminatable assemblies that are not badges, such as illuminatable trim components.

Further, although the exemplary illuminatable assembly 14 is positioned on an exterior front of the vehicle 10, the illuminatable assembly 14 could be located elsewhere on the vehicle 10, including areas on the exterior of the vehicle 10 other than the front end, in areas within an interior of the vehicle 10. Other areas of the vehicle 10 suitable for the illuminatable assembly can include, but are not limited to, a side panel of the vehicle 10, a deck lid of the vehicle 10, a scuff plate of the vehicle 10, a steering wheel of the vehicle 10, etc.

The example illuminatable assembly can be selectively illuminated. When illuminated, a light, such as a white light, is emitted from the illuminatable assembly. Notably, the exemplary illuminatable assembly is illuminated without utilizing light emitting diodes (LEDs).

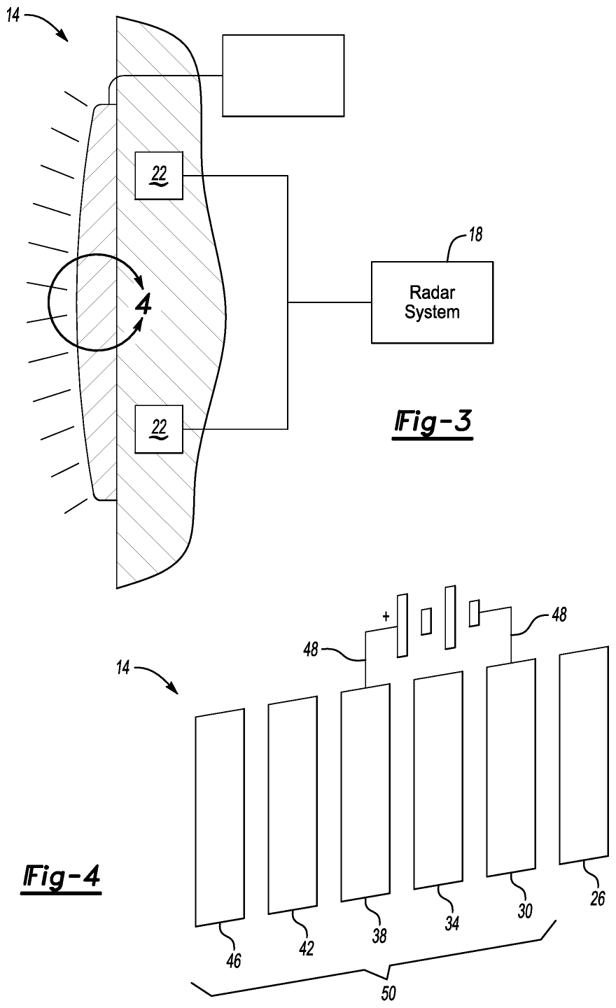

Relative to an orientation of the vehicle 10, the illuminatable assembly is disposed in front of portions of a radar system 18 of the vehicle 10, as schematically shown in FIG. 3. The radar system 18 is linked to radar sensors 22, which are directly aft the illuminatable assembly. The radar sensors 22 are thus hidden from view by the illuminatable assembly.

The illuminatable assembly 14 is, in the exemplary embodiment, constructed from materials that do not overly distort radar waves. This permits the radar sensors 22 to be tucked behind a portion of the illuminatable assembly 14.

With reference now to FIG. 4, the illuminatable assembly 14 includes multiple layers. In the exemplary embodiment, the illuminatable assembly 14 includes a substrate 26, a cathode layer 30, a dielectric layer 34, an anode layer 38, a color conversion layer 42, and an appearance layer 46.

The substrate 26 can be a polymer or polymer-based material. Atop the substrate 26 is the cathode layer 30. The dielectric layer 34 is sandwiched between the cathode layer 30 and the anode layer 38. As can be appreciated, the placement of the anode layer 38 and the cathode layer 30 could be reversed such that the anode layer 38 is positioned closer to the substrate 26 than the cathode layer 30.

In the exemplary embodiment, the cathode layer 30 and the anode layer 38 are thin film layers of sputtered indium. Also, the dielectric layer 34 includes a plurality of perovskite quantum dots that illuminate when charged. Perovskite quantum dots are ionic nanocrystals that can illuminate light when charged. Many perovskite materials can emit visible light when charged or excited by ultraviolet light or electricity.

The color of light emitted from perovskites can be tuned by changed a concentration of halogen precursors as well as the conversion time. For example, if bromine is used as a precursor, adding more bromine can shorten wavelengths of emitted light.

Perovskite quantum dots can be based on, for example, cadmium or lead. Such materials can emit intense colors across the entire visible range of colors. Some other perovskite quantum dots are based on tin or indium. For the dielectric layer 34 of the illuminatable assembly 14, indium may be particularly appropriate since radar can substantially pass through indium metallic foils or films, as understood.

Some cadmium and lead free green perovskite lighting elements can be 13 percent efficient in converting stored energy to light and can achieve 50 kilocandela/square meter of light output using indium-based perovskite quantum dots. In contrast, red indium-based perovskites to achieve slightly greater than 1 percent efficiency with a light output of 1.4 kilocandela/square meter. Accordingly, green perovskites can emit enough light to be used in automotive lighting whereas red perovskites may lack sufficient intensity to be used for automotive lights like tail lamps, marker lamps or CHMSLs.

The illuminatable assembly 14 can, utilizing the green perovskites and color conversion layer 42, emit a white light, which can be particularly desirable for badges, for example

Electrical leads 48 extend from the cathode layer 30 and the anode layer 38 to a power supply. The cathode layer 30 and the anode layer 38 can be selectively powered by the power supply, which electrically activates the cathode layer 30 and anode layer 38 to charge the dielectric layer 34. Charging the dielectric layer 34 illuminates the plurality of perovskite quantum dots within the dielectric layer 34.

The quantum dots illuminate light in a first color, which is green in this example. The light of the first color passes from the dielectric layer 34 through the anode layer 38 outward to the color conversion layer 42.

The color conversion layer 42 is atop the anode layer 38. An exemplary way to convert the green light to white is to filter the green light through a film coated with red rylene dye or purple rylene dye. The red rylene dye can convert the green light to a warm white light. The purple rylene dye can convert the green light to a cool white light.

The color conversion layer 42 could instead include a red or purple phosphor florescent material to perform a “Stokes shift” on the green light and essentially shift the color from green to white. Stokes shifts can be performed by a molecule that can absorb a photon of shorter wavelength (higher frequency or energy) and emit a longer-wavelength photon.

Boron-dipyrromethene (BODIPY) rylene dye is among the most efficient classes of fluorescent dyes. BODIPY rylene dye is about 70 percent efficient performing the color shift vs. a phosphor, which is about 40 percent efficient.

The exemplary color conversion layer 42 includes a rylene dye, and, more particularly, BODIPY rylene dye. The rylene dye of the color conversion layer 42 converts the light emitted from the dielectric layer 34 to a second, different color, which is emitted outward from the color conversion layer 42 through the appearance layer 46. The second color is white in this example.

The color conversion layer 42 could instead, or additionally, include a phosphor material that converts the first color to the second color. The phosphor material could be vacuum metalized to a film of the color conversion layer.

Converting the first color to the second color using the color conversion layer 42 can include adjustments to the amount of blue in the rylene dye or the phosphor material. Adjusting the amount of blue can change the color of the white light emitted from the color conversion layer 42. Changes to the color of the white light can include making the white light warmer or cooler. A warm white light has more yellow, whereas a cool white light has more blue. In one example, the color conversion layer 42 adjusts the light emitted from the dielectric layer 34 such that the light of the second color is from 7000K to 7500K.

The light of the second color is emitted through the appearance layer 46. Thus, when the illuminatable assembly is viewed from a position in front of the vehicle 10, the illuminatable assembly is illuminated in a white light.

In the exemplary embodiment, the appearance layer 46 includes indium and a polymer or polymer-based film. When the illuminatable assembly 14 is not illuminated the appearance layer 46 can give the illuminatable assembly 14 a metallic look, a chrome look, or both. Notably, the light of the second color is emitted through the chrome of the appearance layer 46, rather than about a periphery of the chrome.

The appearance layer 46, in an exemplary embodiment, includes the layer of indium, which is sputtered on a backside of a polymer or polymer-based film.

The use of indium within the illuminatable assembly 14 can help to reduce the illuminatable assembly 14 interfering with the radar signals that communicate to and from the radar sensors 22 of the radar system 18. The radar sensors 22 can thus be located behind the illuminatable assembly 14, which can help conceal the radar sensors 22 from view when viewed from in front of the vehicle 10. In the past, some radar sensors could not be hidden behind a badge due to portions of the badge, such as a circuit board or LED, interfering with communications to and from the radar sensors.

The cathode layer 30, the dielectric layer 34, the anode layer 38, the color conversion layer 42, and the appearance layer 46 can be joined together as a multilayered film 50. When assembling the illuminatable assembly, the substrate 26 can molded against the cathode layer 30 of the multi-layered film 50.

For example, the multi-layered film 50 can be placed within a molding tool, with electrical leads 48 attached to the cathode layer 30 and the anode layer 38. The substrate 26 can then be back injected into a cavity of the molding tool against the multi-layered film 50. The substrate 26 can be molded via relatively low pressure molding to avoid damage to the multi-layered film 50.

In some examples, the multi-layered film 50 can be thermal formed and cut to precise shapes prior to molding the substrate 26 against the multi-layered film 50.

Lighting elements of the multi-layered film 50 can be constructed, in an exemplary embodiment, by printing a metallic layer over a dielectric film and subsequently printing a dielectric layer, a perovskite layer, and finally a clear conductive layer on top. Such a construction has been found to be greater than 50 percent transparent and at least 5 percent efficient, which yields a light output of about 15 candela/square meter.

In this construction, a variety of materials can be used Polyetheretherketone (PEEK) can be used in some examples as it is relatively stable and clear. The bottom metal layer of the multi-layered film can be silver. Most other metals or conductive materials could be used. The construction can include indium-based perovskite quantum dots within the dielectric film. Tin, Cadmium Iodine or lead based dots can also be used. The clear conductive layer can be indium tin oxide, aluminum-doped zinc oxide (ITO AZO). In other example, WO, NiO or silver nano wires could be used.

Generally, in an exemplary embodiment, the multi-layered film 50 can include an outer layer of indium film, which will provide basic “chrome” appearance. The outer layer can be made by sputtering a thin layer of indium to the backside of a plastic film. A second layer of film is coated with rylene dye or phosphor on one side, which is used to convert color of perovskites to white. That second layer is sputtered with a thin film of indium on the other side. This creates the anode used to excite/illuminate quantum dots or a perovskite material. Another film layer includes conventional quantum dots, or perovskite material, suspended in a dielectric material that is printed. A first side of this film layer is placed against the second layer. An opposite second side of this film layer is sputtered with indium to create a cathode used to excite/illuminate the quantum dots or perovskite material. The cathode can be secured to a substrate with an adhesive.

Features of the disclosed examples include an illuminatable vehicle assembly that is compatible with radar, which means that radar waves can efficiently penetrate the assembly. Package space required for the assembly is relatively small as the assembly has a thickness substantially made up of only a multi-layered film and a substrate. The assembly can be illuminated without requiring LEDs and or a circuit board.

Although a specific component relationship is illustrated in the figures of this disclosure, the illustrations are not intended to limit this disclosure. In other words, the placement and orientation of the various components shown could vary within the scope of this disclosure. In addition, the various figures accompanying this disclosure are not necessarily to scale, and some features may be exaggerated or minimized to show certain details of a particular component.

The preceding description is exemplary rather than limiting in nature. Variations and modifications to the disclosed examples may become apparent to those skilled in the art that do not necessarily depart from the essence of this disclosure. Thus, the scope of legal protection given to this disclosure can only be determined by studying the following claims.

What is claimed is:

1. An illuminatable vehicle assembly, comprising:
a dielectric layer that emits light, the dielectric layer disposed between an anode layer and a cathode layer; and
a color conversion layer that converts light emitted from the dielectric layer.

2. The illuminatable vehicle assembly of claim 1, wherein the anode layer is an indium anode layer and the cathode layer is an indium cathode layer.

3. The illuminatable vehicle assembly of claim 1, wherein the dielectric layer comprises quantum dots suspended in a dielectric material.

4. The illuminatable vehicle assembly of claim 1, wherein the dielectric layer comprises a perovskite material suspended in a dielectric material.

5. The illuminatable vehicle assembly of claim 1, further comprising a substrate, wherein the anode layer or the cathode layer is adhered to the substrate.

6. The illuminatable vehicle assembly of claim 1, further comprising a radar sensor adjacent the substrate.

7. The illuminatable vehicle assembly of claim 1, further comprising an outer layer atop the anode layer or the cathode layer, the outer layer including indium secured to a polymer or polymer based film.

8. The illuminatable vehicle assembly of claim 1, wherein the dielectric layer is configured to emit green light, and the color conversion layer is configured to convert the green light such to white light.

9. The illuminatable vehicle assembly of claim 1, wherein the color conversion layer includes a rylene dye.

10. The illuminatable vehicle assembly of claim 1, wherein the color conversion layer includes a phosphor.

11. A vehicle badge assembly, comprising:
a radar sensor;
a substrate adjacent the radar sensor;
a first indium layer atop the substrate;
a dielectric layer atop the first indium layer, the dielectric layer including a plurality of perovskite quantum dots that illuminate when charged;
a second indium layer atop the dielectric layer, the first and second indium layers configured to place a charge across the dielectric layer to illuminate the plurality of perovskite quantum dots;
a color conversion layer atop the second indium layer, the color conversion layer including a Boron-Dipyrromethene rylene dye, the color conversion layer converting a color of light emitted from the plurality of perovskite quantum dots; and
an appearance layer atop the color conversion layer, the appearance layer including indium and a polymer-based film.

12. The vehicle badge assembly of claim 11, wherein the color conversion layer converts green light emitted from the plurality of perovskite quantum dots into white light that is emitted through the appearance layer.

13. An illumination method, comprising:
electrically charging a dielectric layer of a badge to cause the dielectric layer of the badge to emit light having a first color; and
passing the light emitted from the dielectric layer through a color conversion layer that converts the light to a second color different than the first color.

14. The illumination method of claim 13, further comprising sandwiching the dielectric layer between an anode layer and a cathode layer.

15. The illumination method of claim 14, wherein the anode layer is an indium anode layer and the cathode layer is an indium cathode layer.

16. The illumination method of claim 13, wherein the first color is green and the second color is white.

17. The illumination method of claim 13, further comprising placing a radar sensor behind the badge and communicating signals to and from the radar sensor, the signals passing through at least a portion of the badge.

18. The illumination method of claim 13, wherein the dielectric layer comprises a perovskite material suspended in a dielectric material.

19. The illumination method of claim 13, wherein the dielectric layer comprises quantum dots suspended in a dielectric material.

20. The illumination method of claim 13, wherein the color conversion layer includes a rylene dye.
